(19) United States
(12) Patent Application Publication
(10) Pub. No.: US 2017/0031240 A1
(43) Pub. Date: Feb. 2, 2017

(54) APPARATUS FOR ATTACHING PELLICLE

(71) Applicant: Samsung Electronics Co., Ltd., Suwon-si (KR)

(72) Inventor: HAE-YOUNG JEONG, Suwon-si (KR)

(21) Appl. No.: 15/088,542

(22) Filed: Apr. 1, 2016

(30) Foreign Application Priority Data
Jul. 28, 2015 (KR) 10-2015-0106834

(51) Int. Cl. G03F 1/64

(52) U.S. Cl. CPC G03F 1/64

(57) ABSTRACT

Apparatuses for attaching pellicle may be provided. For example, a pellicle attaching apparatus includes a lower supporter supporting a lower surface of a pellicle, an upper supporter supporting an upper surface of a reticle such that a lower surface of the reticle is in contact with a pellicle frame disposed on an upper surface of the pellicle, and a first sound wave generator disposed on the upper surface of the reticle to irradiate ultrasonic waves onto the upper surface of the reticle.

### CROSS-REFERENCE TO RELATED APPLICATION

This application claims priority from Korean Patent Application No. 10-2015-0106834 filed on Jul. 28, 2015 in the Korean Intellectual Property Office, and all the benefits accruing therefrom under 35 U.S.C. 119, the contents of which in its entirety are herein incorporated by reference.

### BACKGROUND

1. Technical Field

The present inventive concepts relate to apparatuses for attaching a pellicle to a reticle and/or driving methods thereof, and more particularly to pellicle attaching apparatuses including a sound wave generator and/or driving methods thereof.

2. Description of the Related Art

In general, a circuit pattern is formed on a wafer through a photolithography process. When performing a photolithography process, a photoresist is coated on the wafer. Then, in order to transfer a circuit pattern formed on a reticle, the coated photoresist is exposed to light. In this case, the exposure is performed such that light of a desired (or alternatively, predetermined) wavelength emitted from a light source is projected onto the reticle and transmitted or reflected light is irradiated to the wafer on which the photoresist is coated, thereby forming a pattern in a desired (or alternatively, predetermined) shape. Then, the exposed photoresist is developed. In this manner, a series of steps are performed.

In this semiconductor manufacturing process, a pellicle is used to protect the surface of the reticle from particles in the air or other contamination. When attaching the pellicle to the surface of the reticle, distortion may occur in the reticle due to a pressure applied to the pellicle and the reticle.

Accordingly, in order to form an accurate fine circuit pattern on the wafer, the pellicle is desired to be attached to the reticle while mitigating or preventing distortion from occurring in the reticle.

### SUMMARY

The present inventive concepts provide pellicle attaching apparatuses capable of mitigating or preventing distortion of a reticle by using ultrasonic waves when a pellicle is attached to a surface of the reticle.

The present inventive concepts also provide driving methods of a pellicle attaching apparatus, which is capable of mitigating or preventing distortion of a reticle by using ultrasonic waves when a pellicle is attached to a surface of the reticle.

In accordance with an aspect of the present inventive concepts, a pellicle attaching apparatus includes a lower supporter supporting a lower surface of a pellicle, an upper supporter supporting an upper surface of a reticle such that a lower surface of the reticle is in contact with a pellicle frame, the pellicle frame on an upper surface of the pellicle, and a first sound wave generator configured to irradiate ultrasonic waves onto the upper surface of the reticle. The first sound wave generator may irradiate ultrasonic waves onto the reticle at which the reticle overlaps with the pellicle frame.

In accordance with an aspect of the present inventive concepts, a pellicle attaching apparatus includes an attaching unit including an upper supporter and a lower supporter arranged in a vertical direction, a driving unit configured to move the lower supporter toward the upper supporter such that a reticle and a pellicle arranged on the lower supporter are attached to the upper supporter and a sound wave generator configured to irradiate ultrasonic waves to one surface of the reticle.

In accordance with an aspect of the present inventive concepts, a pellicle attaching apparatus includes an adhesive between a pellicle frame and a reticle and an ultrasonic wave generator configured to irradiate ultrasonic waves on the reticle.

However, aspects of the present inventive concepts are not restricted to those set forth herein. The above and other aspects of the present inventive concepts will become more apparent to one of ordinary skill in the art to which the present inventive concepts pertains by referencing the detailed description of the present inventive concepts given below.

### BRIEF DESCRIPTION OF THE DRAWINGS

The above and other aspects and features of the present inventive concepts will become more apparent by describing in detail some example embodiments thereof with reference to the attached drawings, in which:

FIG. 1 is a block diagram of a pellicle attaching apparatus according to an example embodiment of the present inventive concepts;

FIG. 2A is a top view of the pellicle attaching apparatus of FIG. 1;

FIG. 2B is a cross-sectional view taken along line A-A of FIG. 2A;

FIGS. 3A to 3C are diagrams for explaining an operation of a pellicle attaching apparatus according to an example embodiment of the present inventive concepts;

FIG. 4 is a cross-sectional view of a pellicle attaching apparatus according to another example embodiment of the present inventive concepts;

FIG. 5 is a cross-sectional view of a pellicle attaching apparatus according to still another example embodiments of the present inventive concepts;

FIG. 6 is a cross-sectional view of a pellicle attaching apparatus according to even another example embodiments of the present inventive concepts;

FIG. 7 is a cross-sectional view of a pellicle attaching apparatus according to yet another example embodiments of the present inventive concepts;

FIG. 8 is a cross-sectional view at a different side (e.g., a side along which a shock absorber is disposed on an upper surface of a reticle) of a pellicle attaching apparatus according to some example embodiments of the present inventive concepts;

FIG. 9A is a top view of a pellicle attaching apparatus according to still further example embodiment of the present inventive concepts;

FIG. 9B is a cross-sectional view of the pellicle attaching apparatus taken along line IX-IX′ of FIG. 9A;

FIG. 10 is a block diagram of an electronic system including a semiconductor device manufactured by using a pellicle attaching apparatus according to some example embodiments of the present inventive concepts; and

FIGS. 11 to 13 show example semiconductor systems to which a semiconductor device manufactured by using a pellicle attaching apparatus according to some example embodiments of the present inventive concept is applicable.

### DETAILED DESCRIPTION OF THE EMBODIMENTS

Advantages and features of the present inventive concepts and methods of accomplishing the same may be understood more readily by reference to the following detailed description of some example embodiments and the accompanying drawings. The present inventive concepts may, however, be embodied in many different forms and should not be construed as being limited to the example embodiments set forth herein. Rather, these example embodiments are provided so that this disclosure will be thorough and complete and will fully convey the inventive concepts to those skilled in the art, and the present inventive concepts will only be defined by the appended claims. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The present inventive concepts will be described with reference to perspective views, cross-sectional views, and/or plan views, in which some example embodiments of the inventive concepts are shown. Thus, the profile of an example view may be modified according to manufacturing techniques and/or allowances. That is, the disclosed example embodiments of the inventive concepts are not intended to limit the scope of the present inventive concepts but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which the inventive concepts belong. It is noted that the use of any and all examples, or example terms provided herein is intended merely to better illuminate the inventive concepts and is not a limitation on the scope of the inventive concepts unless otherwise specified. Further, unless defined otherwise, all terms defined in generally used dictionaries may not be overly interpreted.

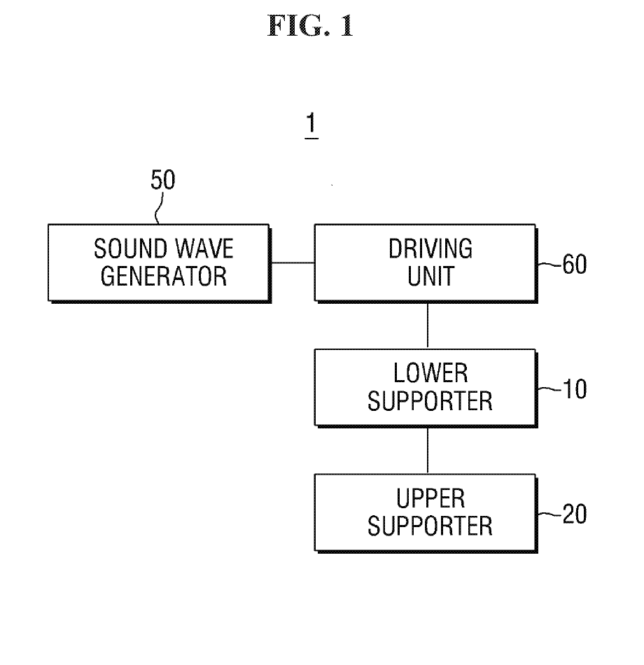

FIG. 1 is a block diagram of a pellicle attaching apparatus according to an example embodiment of the present inventive concepts.

Referring to FIG. 1, a pellicle attaching apparatus I may include a lower supporter 10, an upper supporter 20, a first sound wave generator 50 and a driving unit 60. Each of the lower supporter 10 and the first sound wave generator 50 is connected to the driving unit 60, and may be driven by power received from the driving unit 60. Each component constituting the pellicle attaching apparatus 1 will be described in detail later.

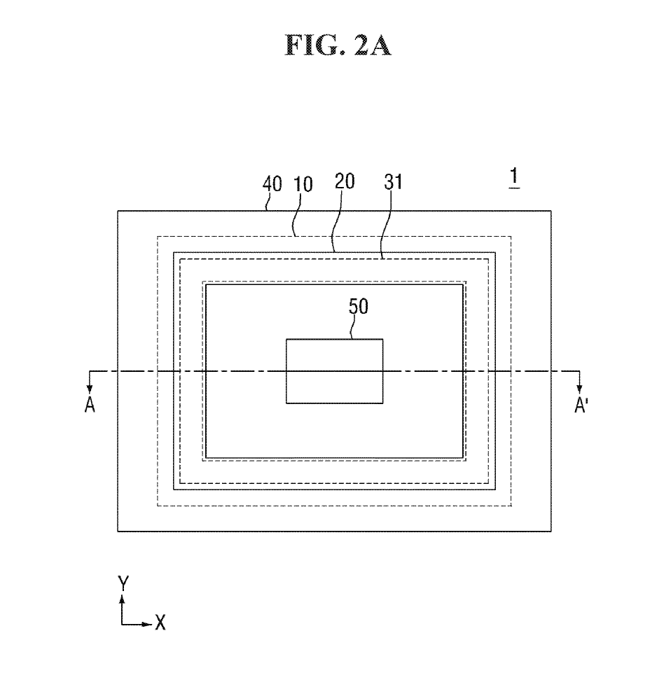

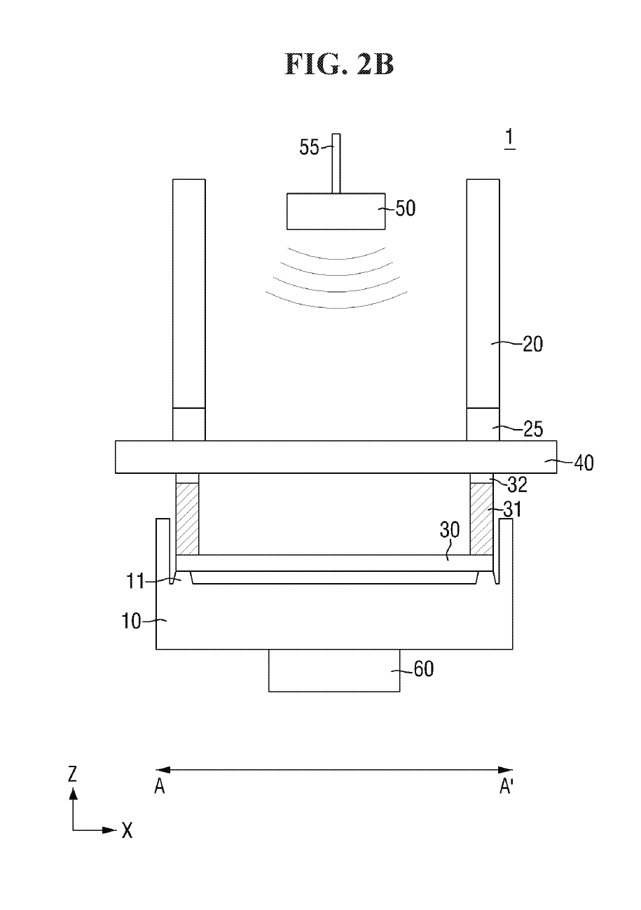

FIG. 2A is a top view of a pellicle attaching apparatus according to an example embodiment of the present inventive concepts. FIG. 2B is a cross-sectional view taken along line A-A′ of FIG. 2A.

Referring to FIGS. 2A and 2B, the lower supporter 10 supports a pellicle 30, a pellicle frame 31 attached to the pellicle 30, and a reticle 40 located on the pellicle frame 31.

The lower supporter 10 may include a protruding portion 11. The protruding portion 11 is formed on the upper surface of the lower supporter 10 and may come into contact with the pellicle 30.

When the pellicle 30 is supported by the lower supporter 10, while being in full contact with the upper surface of the lower supporter 10, scratches or contamination due to particles may occur on the surface of the pellicle 30. Therefore, the protruding portion 11 formed on the upper surface of the lower supporter 10 is configured to minimize the contact area between the lower supporter 10 and the surface of the pellicle 30, thereby minimizing the contamination that may occur on the surface of the pellicle 30.

The protruding portion 11 may be formed on the upper surface of the lower supporter 10 so as to overlap with the pellicle frame 31. That is, when the lower supporter 10 supports the pellicle in a first direction Z, a portion of the pellicle frame 31 having a relatively larger hardness than the pellicle 30 may overlap with the protruding portion 11. Therefore, a part of the force applied to the surface of the pellicle 30 by the lower supporter 10 may be transmitted to the pellicle frame 31 to reduce the distortion that may occur in the pellicle 30 when an excessive pressure is applied to the pellicle 30.

The driving unit 60 may be connected to the lower supporter 10. That is, in a method of driving a pellicle attaching apparatus according to some example embodiments of the present inventive concepts, the driving unit 60 may be configured to move the lower supporter 10 in one or more directions.

The driving unit 60 may be configured to move the lower supporter 10 mainly in the first direction Z, but the present inventive concepts are not limited thereto. That is, the driving unit 60 may be configured to move the lower supporter 10 in any direction (±X, ±Y, ±Z) according to an alignment state of the pellicle 30 and/or the reticle 40.

The reticle 40 may include a pattern printed on one surface thereof so as to be transferred to a photoresist coated on a surface of a semiconductor substrate. By using the reticle 40 having the printed pattern, the light having passed through the reticle 40 may be irradiated on the semiconductor substrate through an optical system.

The reticle 40 may be used in an exposure process using extreme ultraviolet lithography (RN) light, but the present inventive concepts are not limited thereto. That is, in any case where the pellicle can be attached onto the reticle in order to protect the reticle from particles or other contamination, the pellicle attaching apparatus according to some example embodiments of the present inventive concepts may be used.

The pellicle 30 is a protective film which is attached onto the surface on which the pattern of the reticle 40 is formed. The pellicle 30 may be attached to the reticle 40 by the pellicle frame 31, which is disposed on the upper surface of the pellicle 30.

The generation of other contamination or adhesion of particles on a surface of the reticle 40 used in a lithography process may influence the pattern formed on the reticle 40, thereby reducing the reliability of a final semiconductor product. Thus, the pellicle 30 is attached to the reticle 40 to protect the surface of the reticle 40.

The pellicle frame 31 may be disposed along the edge of the upper surface of the pellicle 30. The pellicle frame 31 may include aluminum, but the present inventive concepts are not limited thereto. If the pellicle frame 31 includes aluminum, the Young's modulus or elastic modulus of the pellicle frame 31 may be smaller than the reticle 40.

An adhesive 32 may be disposed between the pellicle frame 31 and the reticle 40. The adhesive 32 may bond the pellicle frame 31 to the reticle 40 after ultrasonic waves are irradiated from the first sound wave generator 50.

The adhesive 32 may be, for example, a hot melt adhesive (HMA). For example, the adhesive 32 may include a styrene-based or acryl-based adhesive, but the present inventive concepts are not limited thereto.

If the adhesive 32 includes a hot melt adhesive, the adhesive 32 may be vibrated by the ultrasonic waves irradiated from the first sound wave generator 50. For example, molecules included in the adhesive 32 may be vibrated periodically. By this vibration, adhesive bonding may be formed between the pellicle frame 31 and the adhesive 32 and/or between the reticle 40 and the adhesive 32.

The upper supporter 20 may be disposed on the upper surface of the reticle 40 to support the upper surface of the reticle 40 such that the lower surface of the reticle 40 is brought into contact with the pellicle frame 31. The upper supporter 20 and the lower supporter 10 may be arranged side by side in the vertical direction to fix and align the pellicle 30 with the reticle 40.

The upper supporter 20 may have a rectangular shape surrounding a portion of the upper surface of the reticle 40.

As described below, the upper supporter 20 may apply to the pellicle 30 and the reticle 40 a relatively small force (e.g., a minimum force), which is sufficient to attach the pellicle 30 to the reticle 40. Because an excessive force or pressure is not desired to be applied to the upper supporter 20 against the pellicle 30 to the reticle 40, the upper supporter 20 may not be connected to the driving unit 60.

Further, the driving unit 60 may be configured to apply to the lower supporter 10 a force, a magnitude of which corresponds to a reaction force of the force applied by the driving unit 60 in the first direction Z to the upper surface of the reticle 40 to attach the pellicle 30 to the reticle 40. Accordingly, distortion of the surface of the reticle 40 due to the force(s) in the first direction Z applied to the reticle 40 may be prevented or mitigated.

The lower supporter 10 and the upper supporter 20 may constitute a fixing unit. That is, the lower supporter 10 and the upper supporter 20 may fix the pellicle 30 and the reticle 40 to be sandwiched between the lower supporter 10 and the upper supporter 20.

In the pellicle attaching apparatus 1 according to some example embodiment of the present inventive concepts, the upper supporter 20 and the pellicle frame 31 may be arranged so as to overlap each other.

A shock absorber 25 may be arranged between the upper supporter 20 and the reticle 40. The shock absorber 25 may absorb a pressure applied by the upper supporter 20 in the first direction Z to the reticle 40 and/or a pressure applied by the lower supporter in the first direction Z 10 to the pellicle 30 and the reticle 40. The shock absorber 25 may absorb vibration that may occur in the first direction Z or a second direction X or the like. Therefore, the movement of the pellicle 30 attached to the reticle 40 may be prevented or mitigated while ultrasonic waves are irradiated by the first sound wave generator 50.

The shock absorber 25 may include, for example, polycarbonate (PC) or acrylonitrile butadiene styrene (ABS), but the present inventive concepts are not limited thereto.

The first sound wave generator 50 may be disposed above the upper surface of the reticle 40 to irradiate ultrasonic waves onto the surface of the reticle 40 to which the pellicle 30 is attached. Further, the first sound wave generator 50 may be disposed in a region above the reticle 40 and surrounded by the upper supporter 20 (e.g., a region above the reticle 40 and exposed by the upper supporter 20).

The first sound wave generator 50 may be connected to the pellicle attaching apparatus 1 via a connection portion 55.

The first sound wave generator 50 may irradiate ultrasonic waves onto the upper surface of the reticle 40 through a space surrounded by the upper supporter 20. The upper supporter 20 has a rectangular shape and includes a sidewall extending in the first direction Z.

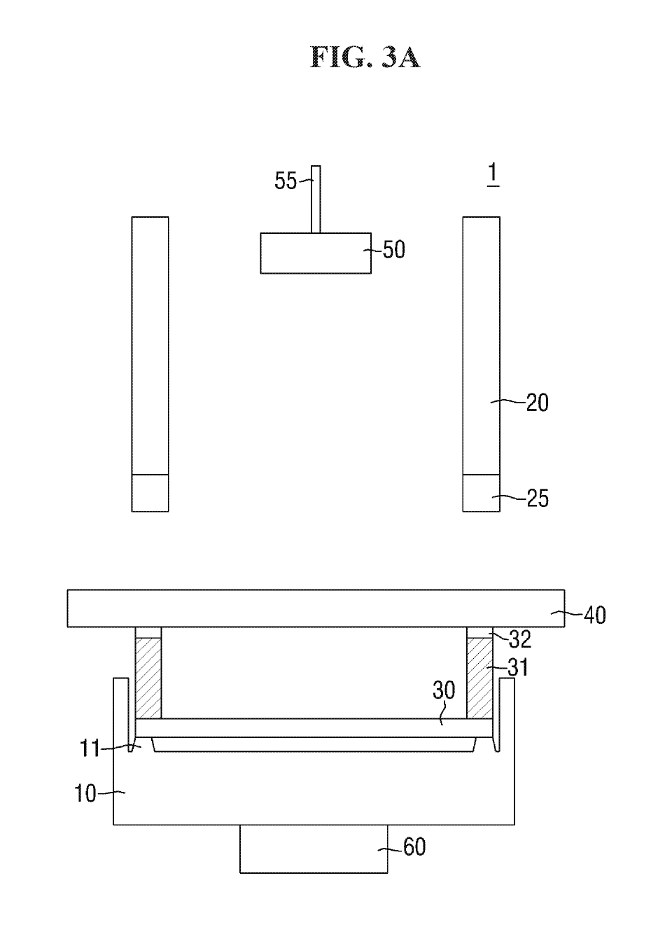

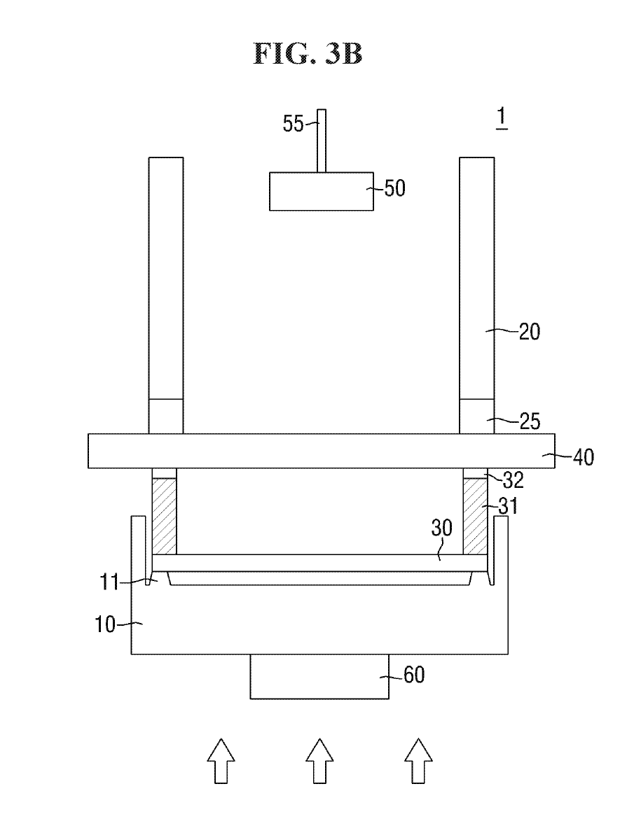

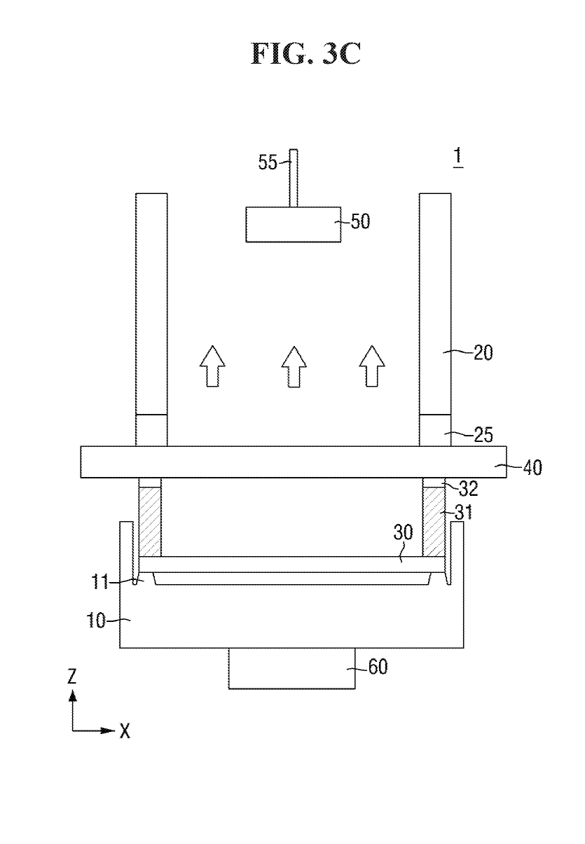

FIGS. 3A to 3C are diagrams for explaining an operation of a pellicle attaching apparatus according to an example embodiment of the present inventive concepts.

Referring to FIG. 3A, the reticle 40 is disposed on the lower supporter 10, and the lower surface of the reticle 40 is brought into contact with the pellicle frame 31 disposed on the upper surface of the reticle 40.

As described above, in order to concentrate a pressure applied to the pellicle 30 on the pellicle frame 31, the positions of the pellicle 30 and the pellicle frame 31 may be aligned with each other on the protruding portion 11 of the lower supporter 10.

In driving methods of the pellicle attaching apparatus according to some example embodiments of the present inventive concepts, the adhesive 32 may be cured before the reticle 40 is arranged on the pellicle frame 31.

The ultrasonic waves irradiated onto the adhesive 32 are more efficiently transferred into an object in a solid phase. Thus, if the adhesive 32 contains water and the hardness of the adhesive 32 is relatively small, during ultrasonic wave irradiation, the ultrasonic waves may be less effectively transferred into the adhesive 32.

The adhesive 32 can be cured by removing a cap covering the adhesive 32 when providing the pellicle 30 and the pellicle frame 31, and exposing the adhesive 32 to the air.

When the adhesive 32 is cured by removing the water from the adhesive 32, the adhesive 32 is hardened and the ultrasonic waves are more effectively transferred into the adhesive 32. Thus, a binding effect between the molecules of a material constituting the adhesive 32 may be increased by the ultrasonic waves. Therefore, an adhesive effect between the pellicle frame 31 and the reticle 40 also may be increased.

Referring to FIG. 3B, by moving the lower supporter 10 for supporting the pellicle 30 and the reticle 40 in the first direction Z, the reticle 40 and the upper supporter 20 are brought into contact with each other. In this case, the shock absorber 25 may be interposed between the upper supporter 20 and the reticle 40 and may be in physical contact with the reticle 40.

The reticle 40 may be deformed when the pellicle frame 31 is attached to the lower surface of the reticle 40 by applying a force to the lower supporter 10 in the first direction Z.

Because the reticle 40 is in contact with the pellicle 30 through the pellicle frame 31, a load may be concentrated on a portion of the lower surface of the reticle 40 at which the pellicle frame 31 is coupled to or is contact with the reticle 40.

Further, for example, if the reticle 40 includes fused silica and the pellicle frame 31 includes aluminum, the elastic modulus of the reticle 40 is about 71.7 GPa, and the elastic modulus of the pellicle frame 31 is about 69 GPa. Accordingly, if a pressure is applied from the lower supporter 10, deformation occurring in the pellicle frame 31, which has a relatively small elastic modulus, may be larger than deformation occurring in the reticle 40, which has a relatively large elastic modulus.

Thus, when the pellicle 30 and the reticle 40 are completely attached to the upper supporter 20, the deformation of the pellicle 30 and the deformation of the pellicle frame 31 may transfer the reticle 40 and cause deformation in the reticle. Thus, accuracy of the exposure process using the reticle 40 can be reduced, and product reliability of the semiconductor device manufactured by the exposure process can be dropped.

In the pellicle attaching apparatus according to some example embodiments of the present inventive concepts, a force causing the lower supporter 10 to push the reticle 40 may have a magnitude insufficient for the adhesive 32 to attach the reticle 40 to the pellicle frame 31. For example, the pellicle 30 and the reticle 40 may be attached to each other by using the ultrasonic waves generated from the first sound wave generator 50, as described below.

The force applied to the lower supporter 10 may have a magnitude sufficient to fix the pellicle 30 and the reticle 40 between the upper supporter 20 and the lower supporter 10 in a sandwiched manner. For example, the force applied to the lower supporter 10 may be equal to or less than 32 kgf/cm².

Referring again to FIG. 2B, the ultrasonic waves may be irradiated to the upper surface of the reticle 40 through a space above the upper surface of the reticle 40 surrounded by the upper supporter 20.

The frequency of the ultrasonic waves irradiated by the first sound wave generator 50 may be about 15 kHz to 70 kHz.

The ultrasonic waves irradiated by the first sound wave generator 50 may be transmitted to the adhesive 32 disposed between the reticle 40 and the pellicle frame 31 through the reticle 40. In other words, the ultrasonic waves irradiated by the first sound wave generator 50 may emit energy while passing through a boundary between the reticle 40 and the adhesive 32.

The stiffness of the reticle 40 including fused silica may be higher than the stiffness of the adhesive 32 including polymer. Accordingly, a propagation velocity of the ultrasonic waves in the reticle 40 may be faster than a propagation velocity of the adhesive 32. Thus, when the ultrasonic waves move from the reticle 40 to the adhesive 32, the energy of the ultrasonic waves may be transmitted at the boundary between the reticle 40 and the adhesive 32 to the adhesive 32.

In general, the adhesive 32 may attach different objects to each other by heat or a pressure applied to the adhesive 32. However, according to the pellicle attaching apparatus according to some example embodiments of the present inventive concepts, the lower supporter 10 may not directly apply a pressure onto the adhesive 32 for attaching different objects to each other.

The adhesive strength of the adhesive 32 may be set proportional to the number of adhesive bonds between molecules included in the adhesive 32 and molecules included in the object in contact with the adhesive 32.

Referring again to FIG. 3B, a contact surface may be formed between the adhesive 32 and fine irregularities formed on a surface of the reticle 40 that is in contact with the adhesive 32, before the ultrasonic waves are irradiated onto the reticle 40. Thus, adhesive bonding may be formed between the molecules included in the adhesive 32 and molecules included in the reticle 40 located on the contact surface.

When the ultrasonic waves are irradiated from the first sound wave generator 50, the molecules included in the adhesive 32 and the molecules included in the reticle 40 may be vibrated periodically. With this vibration, the molecules located at the boundary between the adhesive 32 and the reticle 40 may be attracted to each other, thereby increasing an area of the contact surface formed by the fine irregularities at the boundary. Therefore, the number of adhesive bonds between the molecules located on the contact surface of the adhesive 32 and the reticle 40 may be increased, thereby increasing the adhesive strength of the adhesive 32.

Therefore, in the case of using the pellicle attaching apparatus according to some example embodiments of the present inventive concepts, the ultrasonic waves may be irradiated to the upper surface of the reticle 40 through a space above the upper surface of the reticle 40 surrounded by the upper supporter 20. Thus, an excessive pressure may not be directly applied onto the lower supporter 10 (e.g., the lower surface of the reticle 40) to attach the pellicle 30 to the reticle 40, and thus deformation of the reticle 40 due to such additional pressure may be removed or reduced.

As a result, in the case of using the reticle 40 to which the pellicle 30 is attached through the pellicle attaching apparatus according to some example embodiments of the present inventive concepts, a semiconductor device may have high product reliability due to improved accuracy of the exposure process.

Referring to FIG. 3C, during the irradiation of ultrasonic waves or after completing the irradiation of ultrasonic waves, the particles which are generated in the previous process and attached to the upper surface of the reticle may be suctioned. If the particles are scattered and attached to the upper surface of the reticle 40, accuracy of the exposure process using the reticle 40 can be reduced. Therefore, product reliability of a semiconductor device manufactured by using the reticle 40 may be improved by removing particles on the reticle using the suction process.

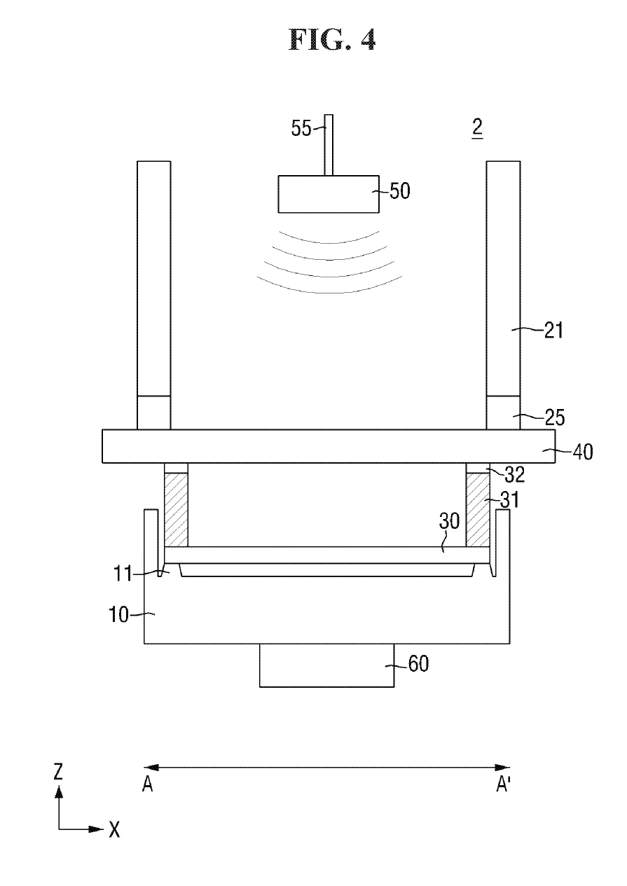

FIG. 4 is a cross-sectional view of a pellicle attaching apparatus according to another example embodiment of the present inventive concepts. A redundant description will be omitted and differences will be mainly described.

Referring to FIG. 4, an upper supporter 21 of a pellicle attaching apparatus 2 may be arranged differently from the previous example embodiment. That is, the upper supporter 21 may be arranged above the pellicle frame 31 such that the upper supporter 21 partially overlaps with the pellicle frame 31.

The ultrasonic wave irradiation area of the pellicle attaching apparatus 2 may be different from the pellicle attaching apparatus 1 (see FIG. 2B). That is, because the upper supporter 21 overlaps with a portion of the pellicle frame 31, the ultrasonic waves may be irradiated onto a portion of the upper surface of the reticle 40 that corresponds to an area of above the pellicle frame 31, which does not overlap with the upper supporter 21.

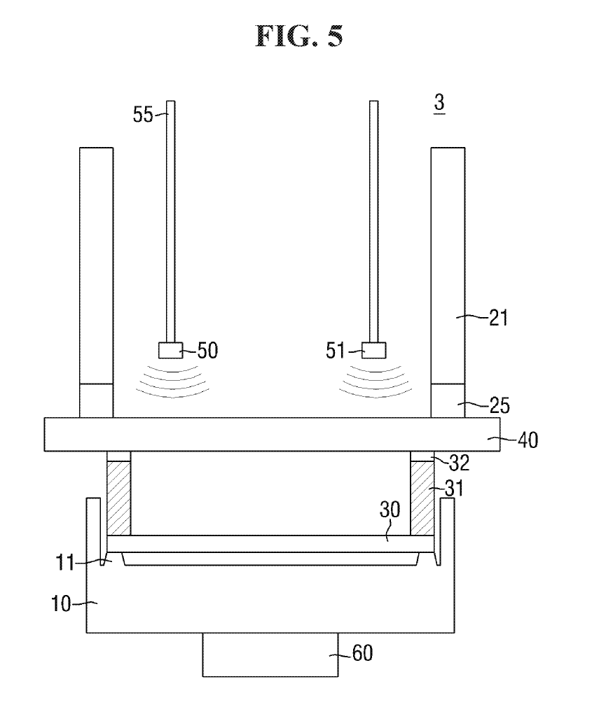

FIG. 5 is a cross-sectional view of a pellicle attaching apparatus according to still another example embodiment of the present inventive concepts.

Referring to FIG. 5, a pellicle attaching apparatus 3 may further include a second sound wave generator 51. The first and second sound wave generators 50 and 51 may be arranged at the same height from the upper surface of the reticle 40.

The first and second sound wave generators 50 and 51 may be arranged adjacent to the upper supporter 21. The first and second sound wave generators 50 and 51 may be arranged such that a distance between the adhesive 32 and the first and second sound wave generators 50 and 51 may be reduced.

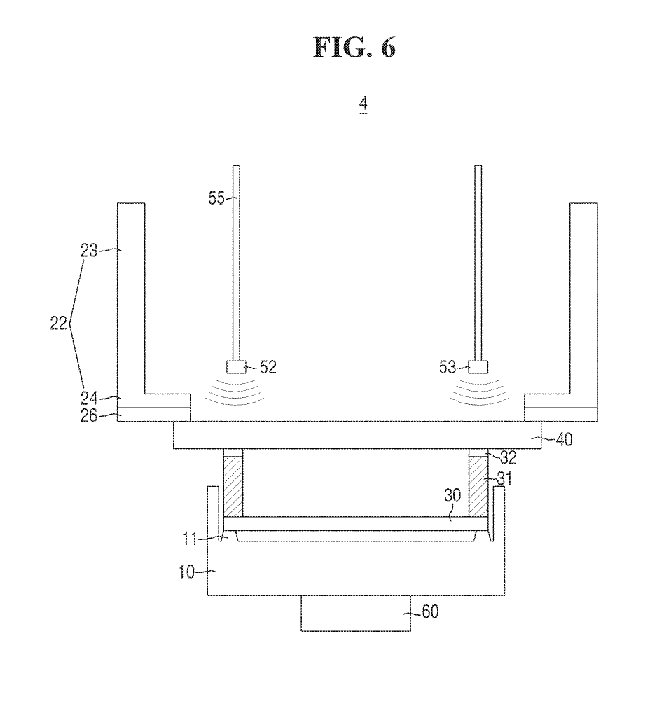

FIG. 6 is a cross-sectional view of a pellicle attaching apparatus according to even another example embodiment of the present inventive concepts.

Referring to FIG. 6, an upper supporter 22 may be arranged so as not to overlap with the pellicle frame 31. Further, third and fourth sound wave generators 52 and 53 may be disposed on the upper surface of the reticle 40 surrounded by the upper supporter 22 such that the third and fourth sound wave generators 52 and 53 overlap with the pellicle frame 31.

The upper supporter 22 may include a sidewall 23 and a bottom wall 24. The bottom wall 24 of the upper supporter 22 and a shock absorber 26 may be disposed to extend from an edge portion of the reticle 40 to the outside of the reticle 40. The sidewall of the upper supporter 22 may be disposed outside the upper surface of the reticle 40. The upper supporter 22 may be connected to the shock absorber 26 by attaching the bottom wall 24 of the upper supporter to the shock absorber 26.

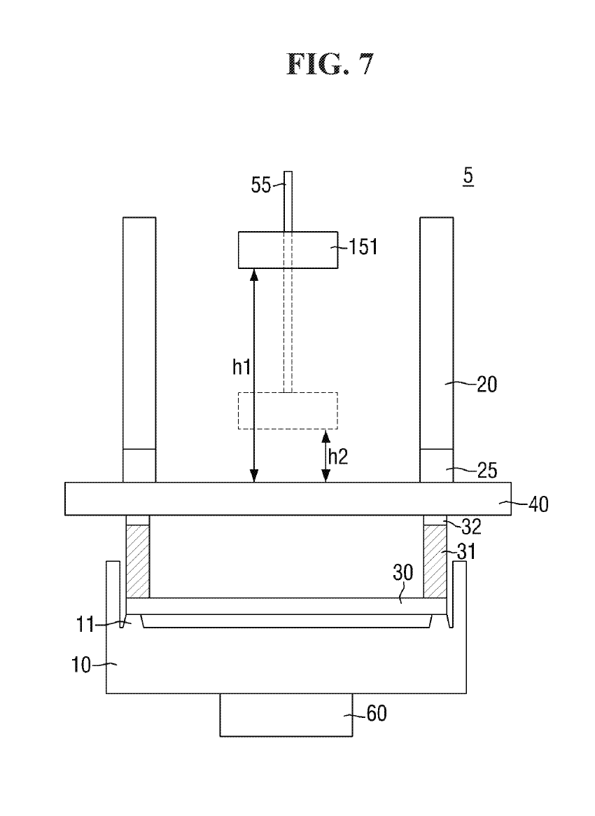

FIG. 7 is a cross-sectional view of a pellicle attaching apparatus according to still yet another example embodiment of the present inventive concepts.

Referring to FIG. 7, a sound wave generator 151 may be configured to move in a direction perpendicular to the reticle 40. For example, the sound wave generator 151 may move from a first height h1 from the upper surface of the reticle 40 to a second height h2 from the upper surface of the reticle 40. The second height is different from the first height.

The connection portion 55 connected to the sound wave generator 151 may be connected to the driving unit 60 to transmit the power generated from the driving unit 60 to the sound wave generator 151.

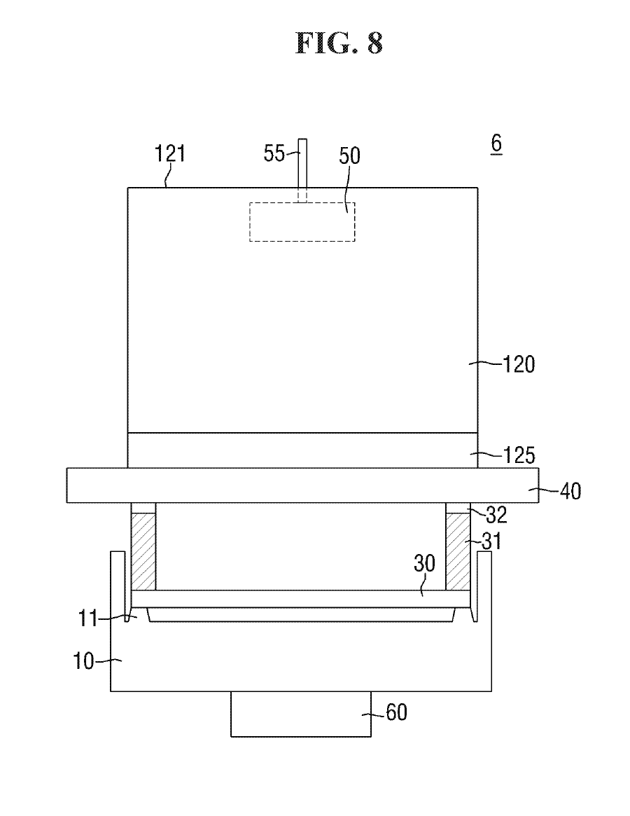

FIG. 8 is a cross-sectional view at a different side (e.g., a side along which a shock absorber is disposed on an upper surface of a reticle) of a pellicle attaching apparatus according to some example embodiment of the present inventive concepts.

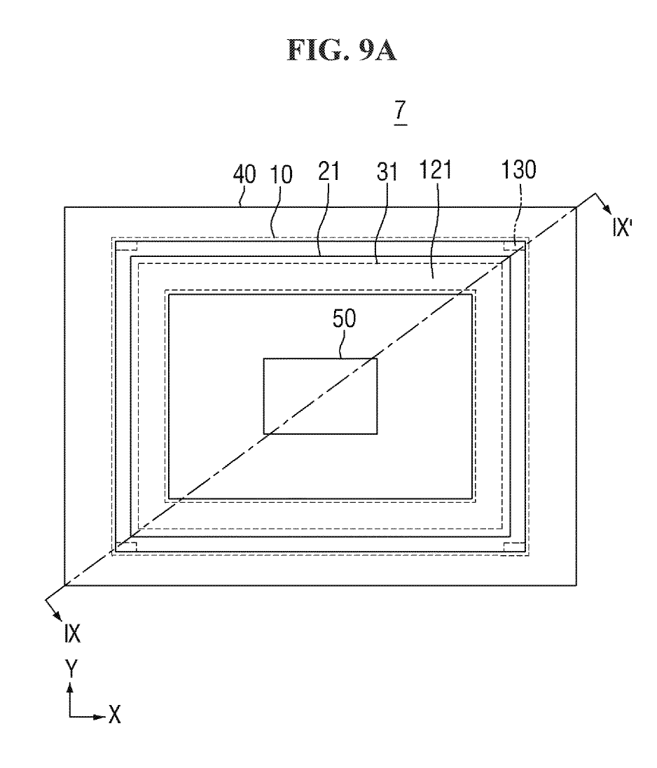

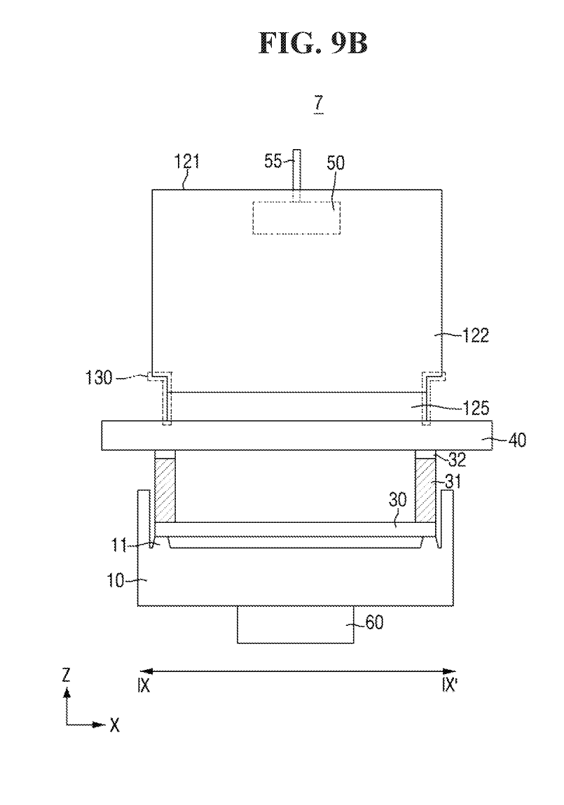

Referring to FIG. 8 (in conjunction with FIG. 9), an upper supporter 120 may include a cover 121 covering the upper surface of the upper supporter 120 and provided on the reticle 10 with a shock absorber 125 interposed. The cover 121 may reflect the ultrasonic waves reflected from the upper surface of the reticle 40 and/or the sidewall of the upper supporter 120, thereby increasing absorption efficiency of the ultrasonic waves irradiated onto the adhesive 32.

The first sound wave generator 50 may be disposed inside a space defined by a sidewall of the upper supporter 120 and the cover 121.

FIG. 9A is a top view of a pellicle attaching apparatus according to still further example embodiment of the present inventive concepts. FIG. 9B is a cross-sectional view of the pellicle attaching apparatus taken along line of FIG. 9A.

Referring to FIGS. 9A and 9B, a hole 130 may be formed in each corner or some corners of the bottom of an upper supporter 122. The hole 130 may allow the ultrasonic waves generated from the first sound wave generator 50 to pass through the upper supporter 122.

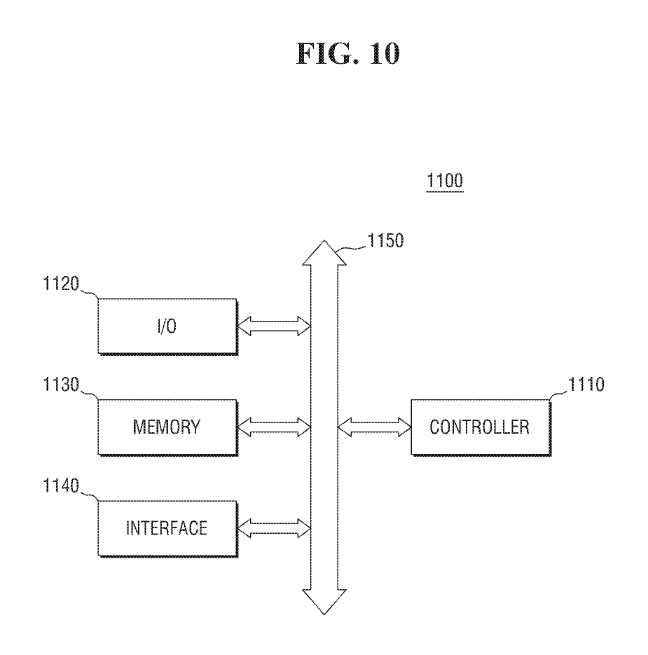

FIG. 10 is a block diagram of an electronic system including a semiconductor device manufactured by using the pellicle attaching apparatus according to some example embodiments of the present inventive concepts.

Referring to FIG. 10, an electronic system 1100 including a semiconductor device manufactured by using the pellicle attaching apparatus according to some example embodiments of the present inventive concepts may include a controller 1110, an input/output (I/O) device 1120, a memory device 1130, an interface 1140, and a bus 1150. The controller 1110, the 110 device 1120, the memory device 1130, and/or the interface 1140 may be coupled to each other through the bus 1150. The bus 1150 refers to a structure or path through which data are transferred.

The controller 1110 may include at least one of a micro-processor, a digital signal processor, a micro-controller and other logic devices capable of performing functions similar to those thereof, The I/O device 1120 may include a keypad, a keyboard and a display device and the like. The memory device 1130 may store data and/or commands. The interface 1140 may serve to transmit/receive data to/from a communication network. The interface 1140 may be of a wired or wireless type. For example, the interface 1140 may include an antenna or a wired/wireless transceiver or the like.

Although not shown, the electronic system 1100 may further include a high-speed DRAM and/or SRAM as an operating memory for improving operation of the electronic system 1100. In this case, as the operating memory, a semiconductor device manufactured by using the pellicle attaching apparatus according to the example embodiments of the present inventive concepts may be employed to improve the product reliability.

The semiconductor device manufactured by using the pellicle attaching apparatus according to the example embodiment of the present inventive concepts may be provided as the memory device 1130 or provided as a part of the controller 1110, the I/O device 1120, and the like.

The electronic system 1100 may be applied to a personal digital assistant (PDA), a portable computer, a web tablet, a wireless phone, a mobile phone, a digital music player, a memory card, or any electronic product capable of transmitting and/or receiving information in a wireless environment.

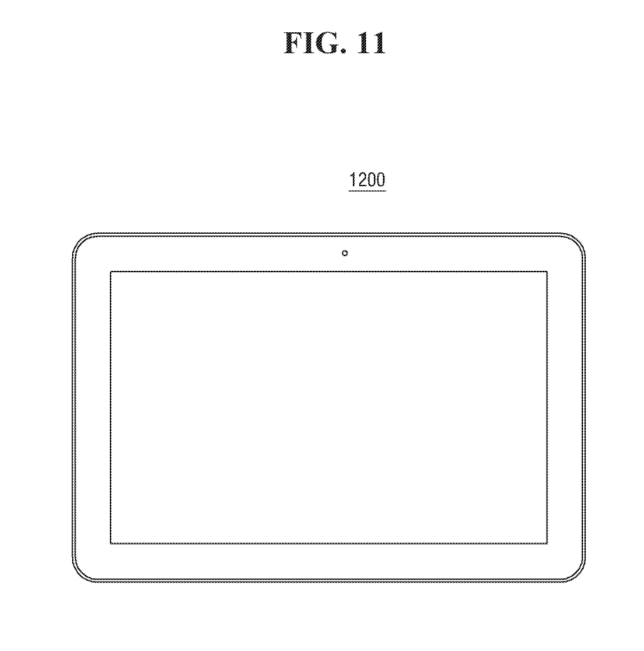

FIGS. 11 to 13 show example semiconductor systems to which a semiconductor device manufactured by using the pellicle attaching apparatus according to some example embodiments of the present inventive concepts is applicable.

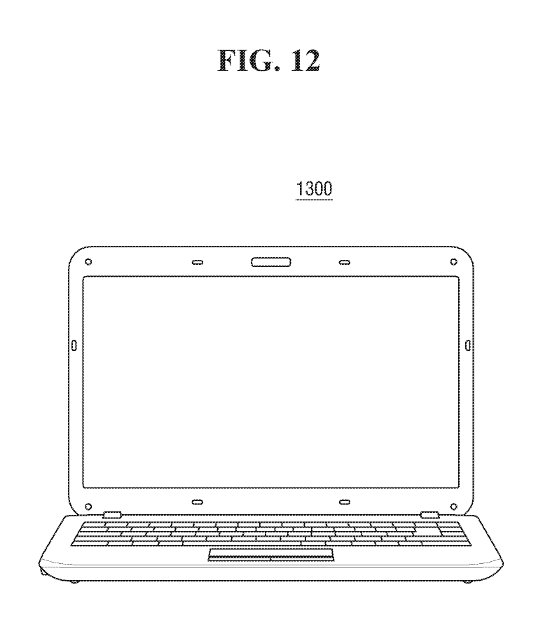

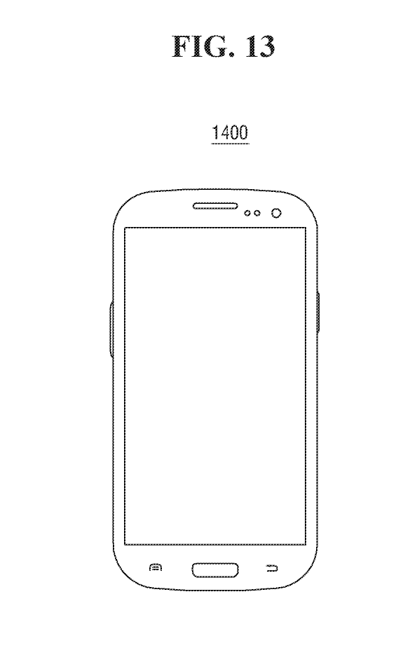

FIG. 11 shows a tablet PC 1200, FIG. 12 shows a laptop 1300, and FIG. 13 shows a smart phone 1400. At least one of the semiconductor devices according to the example embodiments of the present inventive concepts may be used in the tablet PC 1200, the laptop 1300, the smart phone 1400 or the like.

It is obvious to those skilled in the art that the semiconductor device manufactured by using the pellicle attaching apparatus according to the example embodiment of the present inventive concepts can be applied to other integrated circuit devices that are not illustrated.

That is, as examples of semiconductor systems according to the example embodiment of the present inventive concepts, the tablet PC 1200, the laptop 1300, and the smart phone 1400 have been mentioned, but examples of semiconductor systems according to the present example embodiments are not limited thereto.

In some example embodiments of the present inventive concepts, the semiconductor system may be implemented as a computer, a ultra mobile personal computer (UMPC), a workstation, a net-book, a personal digital assistant (PDA), a portable computer (PC), a wireless phone, a mobile phone, an e-book, a portable multimedia player (PMP), a portable game console, a navigation device, a black box, a digital camera, a 3-dimensional television, a digital audio recorder, a digital audio player, a digital picture recorder, a digital picture player, a digital video recorder, a digital video player, or the like.

The example embodiments of the present inventive concepts have been described with reference to the attached drawings, but it may be understood by one of ordinary skill in the art that the present inventive concepts may be performed one of ordinary skill in the art in other specific forms without changing the technical concept or essential features of the present inventive concepts. Further, the above-described example embodiments are merely examples and do not limit the scope of the rights of the present inventive concepts.

What is claimed is:

1. A pellicle attaching apparatus comprising:
a lower supporter supporting a lower surface of a pellicle;
an upper supporter supporting an upper surface of a reticle such that a lower surface of the reticle is in contact with a pellicle frame, the pellicle frame on an upper surface of the pellicle; and
a first sound wave generator configured to irradiate ultrasonic waves onto the upper surface of the reticle.

2. The pellicle attaching apparatus of claim 1, wherein:
the upper supporter has a rectangular shape surrounding a portion of the upper surface of the reticle; and
the first sound wave generator is configured to irradiate the ultrasonic waves onto the reticle exposed by the upper supporter.

3. The pellicle attaching apparatus of claim 2, wherein the upper supporter overlaps with the pellicle frame.

4. The pellicle attaching apparatus of claim 2, wherein
the upper supporter includes a sidewall and a cover,
the cover perpendicularly extends from the sidewall at a top of the sidewall, and
the first sound wave generator is inside the cover.

5. The pellicle attaching apparatus of claim 2, wherein the upper supporter includes a hole formed in a corner thereof such that the ultrasonic waves irradiated from the first sound wave generator passes therethrough.

6. The pellicle attaching apparatus of claim 2, wherein the upper supporter is outside the reticle such that the upper supporter does not to overlap with the pellicle frame.

7. The pellicle attaching apparatus of claim 6, wherein the first sound wave generator is at a region vertically overlapping with the pellicle frame.

8. The pellicle attaching apparatus of claim 1, further comprising:
a second sound wave generator above the upper surface of the reticle at a first height from the upper surface of the reticle and separated from the first sound wave generator,
wherein the first sound wave generator is disposed at a second height from the upper surface of the reticle.

9. The pellicle attaching apparatus of claim 1, further comprising:
a driving unit configured to move the first sound wave generator in a direction perpendicular to the upper surface of the reticle.

10. The pellicle attaching apparatus of claim 1, further comprising:
a shock absorber between the upper supporter and the reticle.

11. The pellicle attaching apparatus of claim 1, wherein
the lower supporter includes a protruding portion on an upper surface of the lower supporter; and
the protruding portion is in contact with the pellicle such that the pellicle frame vertically overlaps with the protrusion portion.

12. A pellicle attaching apparatus comprising:
an attaching unit including an upper supporter and a lower supporter arranged in a vertical direction;
a driving unit configured to move the lower supporter toward the upper supporter such that a reticle and a pellicle arranged on the lower supporter are attached to the upper supporter; and
a sound wave generator configured to irradiate ultrasonic waves to one surface of the reticle.

13. The pellicle attaching apparatus of claim 12, wherein
the upper supporter has a rectangular shape surrounding a portion of the upper surface of the reticle, and
the sound wave generator is configured to irradiate the ultrasonic waves through a space surrounded by the upper supporter.

14. The pellicle attaching apparatus of claim 13, wherein
the upper supporter includes a sidewall and a cover,
the cover perpendicularly extends from the sidewall at a top of the sidewall, and
the sound wave generator is inside the upper supporter.

15. The pellicle attaching apparatus of claim 14, wherein
a corner of a lower portion of the upper supporter includes a hole such that the ultrasonic waves irradiated from the sound wave generator passes therethrough

16. A pellicle attaching apparatus comprising:
an adhesive between a pellicle frame and a reticle; and
an ultrasonic wave generator configured to irradiate ultrasonic waves on the reticle.

17. The pellicle attaching apparatus of claim 16, further comprising:
an upper supporter configured to support the reticle on the pellicle frame;

18. The pellicle attaching apparatus of claim 17, further comprising:
a shock absorber configured to absorb shock between the upper supporter and the reticle.

19. The pellicle attaching apparatus of claim 17, wherein the upper supporter is on the pellicle frame in an overlapping manner.

20. The pellicle attaching apparatus of claim 16, wherein:
the upper supporter includes a sidewall and a cover; and
the ultrasonic wave generator is inside a space defined by the sidewall and the cover of the upper supporter.
